(19) United States
(12) Patent Application Publication
(10) Pub. No.: US 2010/0059363 A1
(43) Pub. Date: Mar. 11, 2010

(54) SURFACE TREATMENT OF ALUMINA FILMS

(76) Inventor: CHEE SENG TOH, Singapore (SG)

Correspondence Address: ROBERTS & ROBERTS, LLP;ATTORNEYS AT LAW, P.O. BOX 484, PRINCETON, NJ, 08542-0484, US

(21) Appl. No.: 11/994,133

(22) PCT Filed: Jun. 29, 2006
(86) PCT No.: PCT/SG2006/000183

§ 371 Date: Oct. 10, 2008

Related U.S. Application Data
(60) Provisional application No. 60/695,160, filed on Jun. 29, 2005.

(51) Int. Cl. C23C 14/34; C07F 5/06

(52) U.S. Cl. 204/192.15; 556/181

(57) ABSTRACT

A method of treating an alumina film comprising the step of exposing said alumina film to a carboxylic acid solution under conditions to reduce the hydropilic properties of the surface of said film.

### TECHNICAL FIELD

The present invention generally relates to a method of treating the surface of an alumina film, such as the surface of an alumina membrane.

### BACKGROUND

Alumina films are widely employed for a variety of applications, especially as membranes in filtration applications, owing to its high pore density, narrow pore size distribution, chemical and thermal stability as well as its rigid support, structure. Particularly, nano-porous alumina membranes are extensively used in solvent filtration in high-performance liquid chromatography, liposome extrusion, micro-filtration and nano-filtration.

In view of the above-outlined properties of alumina, nano-porous alumina membranes are also used in non-filtration applications such as templates for synthesis of nano-wires and nano-rods, as a support for cell cultures, microscopy studies, and as a high surface area support for lipid bi-layer formation.

Alumina films are typically hydrophilic in nature and may therefore not be suitable for applications where a less hydrophilic or a more hydrophobic surface is required. Examples of such applications include protein purification and hydrophobic surfaces for micro-machines such as micro-electro-mechanical systems (MEMs), micro-fluidic devices and micro-engine systems.

In order to extend the use of the alumina films to such applications, surface modification of the alumina films can be carried out to alter the surface properties, i.e., to reduce hydrophlicity or increase hydrophobicity of the surface.

One known method is to graft an anodised aluminium film with poly(ethylene)glycol by activation of the hydroxyl groups of the glycol using chlorosilane, followed by covalent coupling of the poly(ethylene)glycol with the trace hydroxyl (—OH) functional groups on the surface of the alumina film.

Another known method is to chemically modify the surface of an alumina membrane by direct reaction of organocholorosilanes with the surface —OH groups of the alumina.

However, the above methods are generally adopted for surface modification of alumina films which results in silicon-based surfaces only.

Yet another known method involves using high pressure vials to result in physical adsorption of carboxylic acids on aluminium powders covered with surface oxides derived form air oxidation. However, such a method involves the use of high pressure vials which can be expensive to operate.

There is therefore a need to provide a method of treating an alumina film that can modify the surface property of the alumina film by making it less hydrophilic or more hydrophobic.

There is also a need to provide a method of treating an alumina film that is simple and inexpensive to carry out.

There is also a need to provide a method that can overcome or at least ameliorate one or more of the disadvantages described above.

### SUMMARY

According to a first aspect, there is provided a method of treating an alumina film comprising the step of exposing said alumina film to a carboxylic acid solution under conditions to reduce the hydrophilic properties of the surface of said film.

Advantageously, after said exposing step, the surface of the alumina film may remain hydrophilic, albeit having a reduced hydrophilicity, or it may be rendered generally hydrophobic.

In one embodiment, there is provided a method of treating an alumina film comprising the step of exposing said alumina film to a halogen-substituted carboxylic acid solution under conditions to reduce the hydrophilic properties of the surface of said film.

In one embodiment, there is provided a method of treating an alumina film comprising the step of exposing said alumina film to a fluorine-substituted carboxylic acid solution under conditions to reduce the hydrophilic properties of the surface of said film.

According to a second aspect, there is provided a method of treating an alumina film comprising the step of:

(a) providing an alumina film comprising hydroxide;

(b) providing a carboxylic acid solution;

(c) exposing said alumina film to said solution under conditions to react said hydroxide with said carboxylic acid to reduce the hydrophilic properties of the surface of said film.

According to a third aspect, there is provided a method of treating an alumina film comprising the step of exposing said alumina film to a carboxylic acid solution under conditions to react said carboxylic acid with hydroxide of said alumina film, wherein said carboxylic acid is a halogen-substituted carboxylic acid.

According to a fourth aspect, there is provided the use of a treated alumina film produced by the method as defined in any one of the above aspects, to provide a hydrophobic surface for use in a micro-system.

According to a fifth aspect, there is provided the use of a treated alumina film produced by the method as defined in any one of the above aspects, in the purification of protein molecules.

According to a sixth aspect there is provided an alumina film having carboxylate groups bonded to the surface of said film. The carboxylate groups may be substituted with halogen atoms, such as fluorine. The amount of said carboxylate groups bonded to the surface of said film may render said surface generally hydrophobic. The inner body of said film, below said surface, may not comprise any carboxylate groups.

### Definitions

The following words and terms used herein shall have the meaning indicated:

The term “alumina film” as used herein refers to a film of hydrated alumina, and includes fully hydrated alumina such as Al₂O₃.3(H₂O), and partially hydrated alumina.

The term “hydrophilic” as used herein describes surfaces of alumina films that are wettable by aqueous liquids (e.g., water, alcohol solutions etc) deposited thereon. Hydrophilicity and wettability are typically defined in terms of contact angle and the surface tension of the liquids and solids involved. This is discussed in detail in the American Chemical Society publication entitled Contact Angle, Wettability and Adhesion, edited by Robert F. Gould (Copyright 1964). A surface of a film is said to be wetted by a liquid (i.e., hydrophilic) when either the contact angle between the liquid and the film surface is less than 90 degrees, or when the liquid tends to spread spontaneously across the surface of the film surface, both conditions normally co-existing. Conversely, a film surface is considered to be “hydrophobic” if the contact angle is greater than 90 degrees and the liquid does not spread spontaneously across the surface of the film.

The term “alkyl” includes within its meaning monovalent (“alkyl”) and divalent (“alkylene”) straight chain or branched chain saturated aliphatic groups having from 1 to 10 carbon atoms, eg, 1, 2, 3, 4, 5, 6, 7, 8, 9, or 10 carbon atoms. For example, the term alkyl includes, but is not limited to, methyl, ethyl, 1-propyl, isopropyl, 1-butyl, 2-butyl, isobutyl, tert-butyl, amyl, 1,2-dimethylpropyl, 1,1-dimethylpropyl, pentyl, isopentyl, hexyl, 4-methylpentyl, 1-methylpentyl, 2-methylpentyl, 3-methylpentyl, 2,2-dimethylbutyl, 3,3-dimethylbutyl, 1,2-dimethylbutyl, 1,3-dimethylbutyl, 1,2,2-trimethylpropyl, 1,1,2-trimethylpropyl, 2-ethylpentyl, 3-ethylpentyl, heptyl, 1-methylhexyl, 2,2-dimethylpentyl, 3,3-dimethylpentyl, 4,4-dimethylpentyl, 1,2-dimethylpentyl, 1,3-dimethylpentyl, 1,4-dimethylpentyl, 1,2,3-trimethylbutyl, 1,1,2-trimethylbutyl, 1,1,3-trimethylbutyl, 5-methylheptyl, 1-methylheptyl, octyl, nonyl, decyl, and the like.

The term “alkenyl” includes within its meaning monovalent (“alkenyl”) and divalent (“alkenylene”) straight or branched chain unsaturated aliphatic hydrocarbon groups having from 2 to 10 carbon atoms, eg, 2, 3, 4, 5, 6, 7, 8, 9, or 10 carbon atoms and having at least one double bond, of either E, Z, cis or trans stereochemistry where applicable, anywhere in the alkyl chain. Examples of alkenyl groups include but are not limited to ethenyl, vinyl, allyl, 1-methylvinyl, 1-propenyl, 2-propenyl, 2-methyl-1-propenyl, 2-methyl-1-propenyl, 1-butenyl, 2-butenyl, 3-butentyl, 1,3-butadienyl, 1-pentenyl, 2-pententyl, 3-pentenyl, 4-pentenyl, 1,3-pentadienyl, 2,4-pentadienyl, 1,4-pentadienyl, 3-methyl-2-butenyl, 1-hexenyl, 2-hexenyl, 3-hexenyl, 1,3-hexadienyl, 1,4-hexadienyl, 2-methylpentenyl, 1-heptenyl, 2-heptentyl, 3-heptenyl, 1-octenyl, 1-nonenyl, 1-decenyl, and the like.

The term “alkynyl group” as used herein includes within its meaning monovalent (“alkynyl”) and divalent (“alkynylene”) straight or branched chain unsaturated aliphatic hydrocarbon groups having from 2 to 10 carbon atoms and having at least one triple bond anywhere in the carbon chain. Examples of alkynyl groups include but are not limited to ethynyl, 1-propynyl, 1-butynyl, 2-butynyl, 1-methyl-2-butynyl, 3-methyl-1-butynyl, 1-pentynyl, 1-hexynyl, methylpentynyl, 1-heptynyl, 2-heptynyl, 1-octynyl, 2-octynyl, 1-nonyl, 1-decynyl, and the like.

The term “aromatic”, or as used herein refers to monovalent (“aryl”) and divalent (“arylene”) single, polynuclear, conjugated and fused residues of aromatic hydrocarbons having from 6 to 10 carbon atoms. Examples of such groups include benzyl, phenyl, biphenyl, naphthyl, phenanthrenyl, and the like.

The term “hydroxide” refers to —OH group. The term “carboxylate” refers to the conjugate base of a carboxylic acid.

The term “halogen” or variants such as “halide” or “halo” as used herein refers to fluorine, chlorine, bromine and iodine.

The term “substituted” means that the specified compound, group or moiety bears one or more substituents.

The term “optionally substituted” means that the specified group is unsubstituted or substituted by one or more substituents.

Unless specified otherwise, the terms “comprising” and “comprise”, and grammatical variants thereof, are intended to represent “open” or “inclusive” language such that they include recited elements but also permit inclusion of additional, unrecited elements.

As used herein, the term “about”, typically means ±5% of the stated value, more typically ±4% of the stated value, more typically ±3% of the stated value, more typically, ±2% of the stated value, even more typically ±1% of the stated value, and even more typically ±0.5% of the stated value.

Throughout this disclosure, certain embodiments may be disclosed in a range format. It should be understood that the description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

### DETAILED DISCLOSURE OF EMBODIMENTS

Exemplary, non-limiting embodiments of the method of treating alumina, will now be disclosed.

The method of treating the alumina film comprises the step of:

(a) exposing said alumina film to a carboxylic acid solution under conditions to reduce the hydrophilic properties of the surface of said film.

In one embodiment, the alumina film is a membrane. The conditions of the exposing step (a) are such that the surface of the alumina film, after treatment, can have a contact angle selected from the group consisting of at least about 85°, at least about 90°, at least about 92°, at least about 94°, at least about 96°, at least about 98°, at least about 100°, at least about 102°, at least about 104°, at least about 106°, at least about 108°, at least about 110°, at least about 112°, at least about 114°, at least about 116°, at least about 118°, at least about 120°, at least about 122°, at least about 124°, at least about 126°, at least about 128°, at least about 130°, at least about 132°, at least about 134°, at least about 136°, at least about 138° and at least about 140°.

The conditions of said exposing step (a) may comprise the step of:

(b) refluxing said alumina film in said carboxylic acid solution at a temperature, pressure and time effective to at least partially react said carboxylic acid with hydroxide of said alumina film.

The refluxing step (b) may comprise the step of:
(b1) maintaining said temperature at or above the boiling point of the carboxylic acid solution.

The temperature in said maintaining step (b1) may be selected from the group consisting of: about 60° C. to about 100° C.; about 60° C. to about 90° C.; about 60° C. to about 80° C.; about 60° C. to about 70° C.; about 70° C. to about 100° C.; about 80° C. to about 100° C. and about 90° C. to about 100° C.

The refluxing step (b) may comprise the step of:
(b2) refluxing said alumina film in said carboxylic acid solution for a time selected from the group consisting of: about 2 hours to about 5 hours; about 3 hours to about 5 hours; about 4 hours to about 5 hours; about 2 hours to about 4 hours; and about 2 hours to about 3 hours.

The refluxing step (b) can be undertaken in a vacuum.

The refluxing step (b) may comprise the step of:
(b3) maintaining the gauge pressure at about 20 kPa to about 160 kPa.

The method may comprise, after step (b), the step of:

(c) removing said treated alumina film from said carboxylic acid solution.

The method may comprise, after step (c), the step of:

(d) washing said treated alumina film with an inert solvent.

The method as claimed in claim 15, comprising, after step (d), the step of:

(e) drying said treated alumina.

Untreated alumina films are typically hydrophilic in nature, and are therefore restricted to filtration applications involving preferential binding of water to the surface of the membrane over other materials, or other applications requiring a hydrophilic surface.

It has surprisingly been found that alumina films treated by the disclosed method can have reduced hydrophlicity at the surface, thereby rendering the treated alumina films suitable for applications where a less hydrophilic surface or more hydrophobic surface is required. It is thought that the lower hydrophilicity or greater hydrophobicity of the alumina film surface is due to the chemisorption of the carboxylate groups onto the surface structure of the films, as can be determined from the observed 0.3 eV to 1 eV shifts in the Aluminium 2p peak position in XPS studies described in Example 11 below.

Exemplary applications where a less hydrophilic surface is required are providing hydrophobic surfaces in micro-systems, and separation or purification of protein molecules.

### Alumina Film

The alumina film can be a membrane. The alumina membrane may be obtained commercially, for example, from Fischer Scientific International, a company incorporated in the United States of America. Exemplary alumina membranes that can be treated by the method include Whatman™ Anodisc™ 25 of 60 μm thickness having 0.1 μm nominal pore size, Whatman™ Anodisc™ 13 of 60 μm thickness having 0.02 μm nominal pore size, and Whatman™ Anodisc™ 47 of 60 μm thickness having 0.2 μm nominal pore size.

The alumina membrane can also be synthesised in the laboratory using a Radio Frequency (RF) Magnetron sputtering apparatus (for example, Discovery™ 18 Sputtering system). The synthesis of the alumina membrane can involve RF sputtering an aluminium target to form an aluminium film on a substrate (for example, a glass substrate), followed by anodising the aluminium film with oxalic acid (HO₂—C—C—O₂H) to form the alumina membrane. The alumina membrane can then be rinsed with an inert solvent and dried in an oven.

During anodisation, a significant amount of acid anions are incorporated onto the surface of the alumina membrane, and the oxalate anion may be hydrogen bonded to the hydroxide groups on the surface of the alumina. The adsorbed oxalate anion on the surface of the alumina membrane can inhibit or reduce the reaction between the hydroxide group of the alumina and the carboxylate group of the carboxylic acid in the exposing step (a). Accordingly, to remove the adsorbed oxalate anions from the surface of the alumina membrane, the membrane can be immersed in an acid solution (i.e., phosphoric acid solution), to etch away the outer surface of the alumina membrane and thereby remove the adsorbed oxalate anions.

Suitable acids for removing the oxalic acid can be an inorganic acid selected from the group consisting phosphoric acid, sulphuric acid, hydrochloric acid, nitric acid, and combinations thereof.

Accordingly, the disclosed method may comprise, before step (a), the step of:

(f) forming an aluminium film on a substrate by RF sputtering of an aluminium target; and

(g) anodising said formed aluminium film to form said alumina film.

The method may comprise, after step (g) but before step (a), the step of:

(i) immersing said alumina film into an acid.

### Carboxylic Acid Solution

The carboxylic acid can be of the formula R(COOH)ₙ, wherein
R is an aliphatic hydrocarbon group or an aromatic hydrocarbon group; and
n is 1 or 2.

R can be an optionally halogen-substituted aliphatic hydrocarbon selected from the group consisting of straight or branched chain alkyls, alkenyls, alkynyls and combinations thereof.

R can also be an optionally halogen-substituted aromatic hydrocarbon selected from the group consisting of benzyl, toluyl, xylyl, naphthyl and combinations thereof.

Where R is an optionally halogen-substituted aliphatic hydrocarbon, R can be an alkyl group having 1 to 6 carbon atoms, an alkenyl group having 2 to 6 carbon atoms or alkynyl group having 2 to 6 carbon atoms.

The carboxylic acid in the carboxylic solution can be a halogen-substituted carboxylic acid.

The exposing of the alumina film to a carboxylic acid solution, particularly a halogen-substituted carboxylic acid solution, and more particularly a fluorinated carboxylic acid solution, can increase the hydrophobicity or reduce the hydrophlicity of the surface of the alumina film. Carboxylate groups, particularly halogenated carboxylate groups, and more particularly fluorinated carboxylate groups, are generally hydrophobic in nature, i.e., less hydrophilic than the alumina film. Accordingly, the chemisorption of these groups onto the surface of the alumina film can render the surface less hydrophilic or more hydrophobic.

Advantageously, the halogenated carboxylic acid solution facilitates determination of surface coverage of the carboxylic acid in X-Ray Photoelectron Spectroscopy (XPS) studies of the surface, as the halogen atom can function as a unique marker in view of the high contaminant levels of Carbon and Oxygen atoms on the surface.

The number of halogen atoms in the halogen-substituted carboxylic acid can be in the range selected from the group consisting of 1 to 10, 1 to 9, 1 to 8, 1 to 7, 1 to 6, 1 to 5, 2 to 10, 3 to 10, 4 to 10, 5 to 10, 6 to 10, 7 to 10, 8 to 10, 9 to 10.

The halogen can be fluorine and the corresponding halogen-substituted carboxylic acid is accordingly a fluorine-substituted carboxylic acid.

The fluorine-substituted carboxylic acid may be selected from the group consisting of fluorine-substituted acetic acid, fluorine-substituted propanoic acid, fluorine-substituted butanoic acid, fluorine-substituted pentanoic acid, fluorine-substituted hexanoic acid and combinations thereof.

The halogen-substituted carboxylic acid can be a fluorine-substituted carboxylic acid selected from the group consisting of fluorine-substituted benzoic acid, fluorine-substituted toluic acid, fluorine-substituted naphthalic acid and combinations thereof.

The carboxylic acid solution may comprise the carboxylic acid dissolved in an organic solvent. The organic solvent can be a non-polar solvent. The non-polar solvent can be an optionally halogen-substituted organic solvent.

The halogen-substituted organic solvent can provide a non-polar environment for the reaction between the carboxylate groups and the hydroxide groups. It is thought that such an environment generally favours the formation of less polar bonded moiety, such as the reaction between the carboxylate groups of the carboxylic acid with the hydroxide groups of the alumina film.

Additionally, the organic carboxylic acids generally have low solubility in water or aqueous solution, and are generally more soluble in organic solvents such as those disclosed herein.

The optionally halogen-substituted aliphatic hydrocarbon may be selected from the group consisting of straight or branched chain alkanes, ketones, ethers and mixtures thereof The organic solvent can be an alkane having 1 to 6 carbon atoms, a ketone having 2 to 6 carbon atoms or an ether having 2 to 6 carbon atoms. The number of halogen atoms in the halogen-substituted organic solvent can be in the range selected from the group consisting of 1 to 6, 1 to 5, 1 to 4, 1 to 3, 2 to 6, 3 to 6 and 4 to 6.

The halogen may be chlorine and the corresponding halogen-substituted organic solvent is accordingly chlorine-substituted organic solvent.

The chlorine-substituted organic solvent may be selected from the group consisting of chloroethane chloropropane, chlorobutane, chloropentane, chlorohexane and combinations thereof.

The carboxylic acid solution can have a concentration selected from the group consisting of: about 0.01M to about 0.1M; about 0.03M to about 0.1M; about 0.07M to about 0.1M; about 0.01M to about 0.7M; and about 0.01M to about 0.3M.

### BRIEF DESCRIPTION OF DRAWINGS

The accompanying drawings illustrate a disclosed embodiment and serve to explain the principles of the disclosed embodiment. It is to be understood, however, that the drawings are designed for purposes of illustration only, and not as a definition of the limits of the invention.

FIG. 1 shows an X-ray Photoelectron Spectroscope (XPS) Al 2p spectra taken from the surface of untreated alumina membrane of Examples 1 to 3;

FIG. 2 shows an XPS Al 2p spectra taken from the surface of treated alumina membrane of Example 1;

FIG. 3 shows an XPS Al 2p spectra taken from the surface of treated alumina membrane of Example 2;

FIG. 4 shows an XPS Al 2p spectra taken from the surface of treated alumina membrane of Example 3;

FIG. 5 shows a combined XPS Al 2p spectra of FIGS. 1 to 4;

FIG. 6 shows an XPS C 1s spectra taken from the surface of untreated alumina membrane of Examples 1 to 3;

FIG. 7 shows an XPS C 1s spectra taken from the surface of treated alumina membrane of Example 1;

FIG. 8 shows an XPS C 1s spectra taken from the surface of treated alumina membrane of Example 2;

FIG. 9 shows an XPS C 1s spectra taken from the surface of treated alumina membrane of Example 3;

FIG. 10 shows an XPS F 1s spectra taken from the surface of untreated and treated alumina membranes of Examples 1 to 3;

FIG. 11 shows an XPS Al 2p spectra taken from the surface of untreated and treated alumina membranes of Examples 4 to 6;

FIG. 12 shows an XPS C 1s spectra taken from the surface of untreated alumina membrane of Examples 4 to 6;

FIG. 13 shows an XPS C 1s spectra taken from the surface of treated alumina membrane of Example 4;

FIG. 14 shows an XPS C 1s spectra taken from the surface of treated alumina membrane of Example 5;

FIG. 15 shows an XPS C 1s spectra taken from the surface of treated alumina membrane of Example 6;

FIG. 16 shows an XPS F 1s spectra taken from the surface of untreated and treated alumina membranes of Examples 4 to 6;

FIG. 17 shows an X-ray Photoelectron Spectroscope (XPS) Al 2p spectra taken from the surface of untreated alumina membrane of Examples 7 to 9;

FIG. 18 shows an XPS Al 2p spectra taken from the surface of treated alumina membrane of Example 7;

FIG. 19 shows an XPS Al 2p spectra taken from the surface of treated alumina membrane of Example 8;

FIG. 20 shows an XPS Al 2p spectra taken from the surface of treated alumina membrane of Example 9;

FIG. 21 shows a combined XPS Al 2p spectra of FIGS. 17 to 20;

FIG. 22 shows an XPS C 1s spectra taken from the surface of untreated alumina membrane of Examples 7 to 9;

FIG. 23 shows an XPS C 1s spectra taken from the surface of treated alumina membrane of Example 7;

FIG. 24 shows an XPS C 1s spectra taken from the surface of treated alumina membrane of Example 8;

FIG. 25 shows an XPS C 1s spectra taken from the surface of treated alumina membrane of Example 9;

FIG. 26 shows an XPS F 1s spectra taken from the surface of untreated and treated alumina membranes of Examples 7 to 9;

FIGS. 27 to 31 show Scanning Electron Microscope (SEM) micrographs of glass-supported membranes of Example 12 exposed to phosphoric acids for 0 minutes, 15 minutes, 30 minutes, 45 minutes and 60 minutes respectively.

### DETAILED DISCLOSURE OF A PREFERRED EMBODIMENT

Non-limiting examples, including the best mode, will be further described in greater detail by reference to specific Examples, which should not be construed as in any way limiting the scope of the invention.

### Example 1

### Treatment of Commercially Available Membrane Using Trifluoroacetic Acid Solution

An alumina membrane (Whatman™ Anodisc™ 25) having a thickness of 60 μm and 0.1 μm nominal pore size, was obtained from Fischer Scientific International, a company incorporated in the United States of America.

A halogenated carboxylic acid solution was prepared by dissolving 0.03 moles of trifluoroacetic acid (99 vol. %) in one litre (1000 cm³) of pure 1,2-dichloroethane.

The alumina membrane was immersed in the carboxylic acid solution, and the carboxylic acid solution was refluxed at 60° C. for 2 hours. The refluxing was carried out in an enclosed flask having an outlet connected to a Liebig condenser, such that any vapour given off during the heating condensed and flowed back into the carboxylic acid solution.

The alumina membrane was removed from the carboxylic acid solution and was rinsed with de-ionised water to remove any residual 1,2-dichloroethane. The alumina membrane was subsequently dried in an oven at 45° C. for 4 hours.

### Example 2

### Treatment of Commercially Available Membrane Using Perfluoropentanoic Acid

The alumina membrane of Example 1 was treated in accordance with the method described in Example 1, except that the halogenated carboxylic acid used in this Example was perfluoropentanoic acid.

### Example 3

### Treatment of Commercially Available Membrane Using 2,3,4,5,6-Pentafluorobenzoic Acid

The alumina membrane of Example 1 was treated in accordance with the method described in Example 1, except that the halogenated carboxylic acid used in this Example was 2,3,4,5,6-pentafluorobenzoic acid.

### Example 4

### Treatment of Laboratory Synthesised Alumina Membrane Using Trifluoroacetic Acid

An aluminium film was formed on a microscopy glass slide by RF magnetron sputtering (80 W; power density of 7.1 W cm⁻²) using an aluminium target in an atmosphere of argon at 6.67×10⁻⁶ bar (5×10⁻³ Torr). An alligator clip was used to connect the aluminium film to a direct current (DC) power supply. A platinum gauze counter-electrode was provided and an anodisation voltage was applied between the aluminium film and the platinum counter-electrode. Anodisation was performed at ambient temperature for 7 minutes at 40 V in a 0.10M oxalic acid solution (HO₂—C—C—O₂H). The anodised film was then rinsed with 18MΩ-cm resistivity water and immersed for 5 minutes in an aqueous solution containing 0.20M chromic acid and 0.30M phosphoric acid. The film was subsequently rinsed with water, dried in air and re-anodised at 40V for 7 minutes in the oxalic acid solution to form the alumina membrane. The alumina membrane was rinsed with de-ionised water and dried in an oven at 60° C. for 2 hours. The formed alumina membrane has a thickness of about 400 nm and the pores have an average diameter of 20 nm.

The alumina membrane was subsequently treated using the method as described in Example 1.

### Example 5

### Treatment of Laboratory Synthesised Alumina Membrane Using Perfluoropentanoic Acid

An alumina membrane was formed on a microscopy glass slide using the method as described in Example 4, and the formed alumina membrane was treated using the method as described in Example 1, except that the halogenated carboxylic acid used in the Example was perfluoropentanoic acid.

### Example 6

### Treatment of Laboratory Synthesised Alumina Membrane Using 2,3,4,5,6-Pentafluorobenzoic Acid

An alumina membrane was formed on a microscopy glass slide using the method as described in Example 4, and the formed alumina membrane was treated using the method as described in Example 1, except that the halogenated carboxylic acid used in the Example was 2,3,4,5,6-pentafluorobenzoic acid.

### Example 7

### Treatment of Laboratory Synthesised Alumina Membrane Using Trifluoroacetic Acid

An alumina membrane was formed on a microscopy glass slide using the method as described in Example 4, and was immersed in phosphoric acid solution (3 vol. %) for 30 minutes at ambient temperature. The alumina membrane was removed from the phosphoric acid solution and was rinsed with de-ionised water.

The alumina membrane was subsequently treated using the method as described in Example 1.

### Example 8

### Treatment of Laboratory Synthesised Alumina Membrane Using Perfluoropentanoic Acid

An alumina membrane was formed on a microscopy glass slide using the method as described in Example 4, and was immersed in phosphoric acid solution (3 vol. %) for 30 minutes at ambient temperature. The alumina membrane was removed from the phosphoric acid solution and was rinsed with de-ionised water.

The alumina membrane was subsequently treated using the method as described in Example 1, except that the halogenated carboxylic acid used in the Example is perfluoropentanoic acid.

### Example 9

### Treatment of Laboratory Synthesised Alumina Membrane Using 2,3,4,5,6-Pentafluorobenzoic Acid

An alumina membrane was formed on a microscopy glass slide using the method as described in Example 4, and was immersed in phosphoric acid solution (3 vol. %) for 30 minutes at ambient temperature. The alumina membrane was removed from the phosphoric acid solution and was rinsed with de-ionised water.

The alumina membrane was subsequently treated using the method as described in Example 1, except that the halogenated carboxylic acid used in the Example was 2,3,4,5,6-pentafluorobenzoic acid.

### Example 10

### Analysis of Treated Membranes of Examples 1 to 9

### Examples 1 to 3

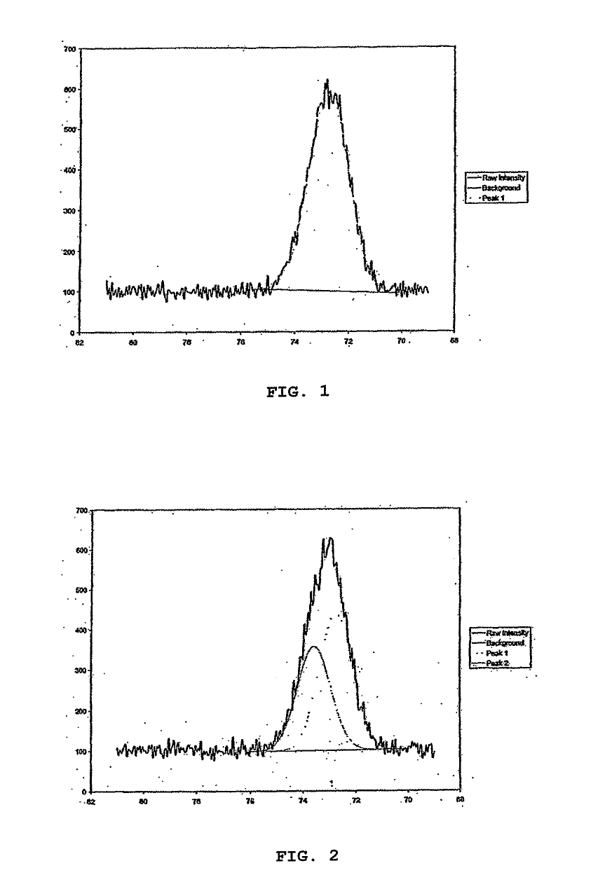

The untreated alumina membrane (Whatman™ Anodisc™ 25) was analysed using an X-ray photoelectron spectroscope (XPS) to study the 2p orbital of aluminium atoms on the surface of the untreated alumina membrane. An XPS spectra depicting the analysis result is shown in FIG. 1.

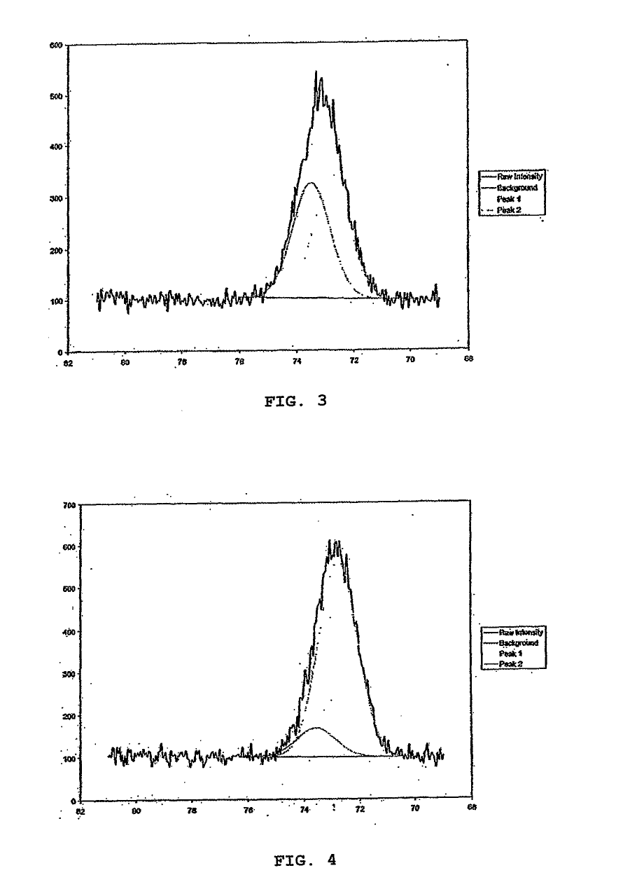

The treated membranes of Examples 1 to 3 were also analysed using the XPS to study the 2p orbital of aluminium atoms on the surface of the treated alumina membranes, and XPS spectras depicting the analysis results are shown in FIGS. 2 to 4 respectively.

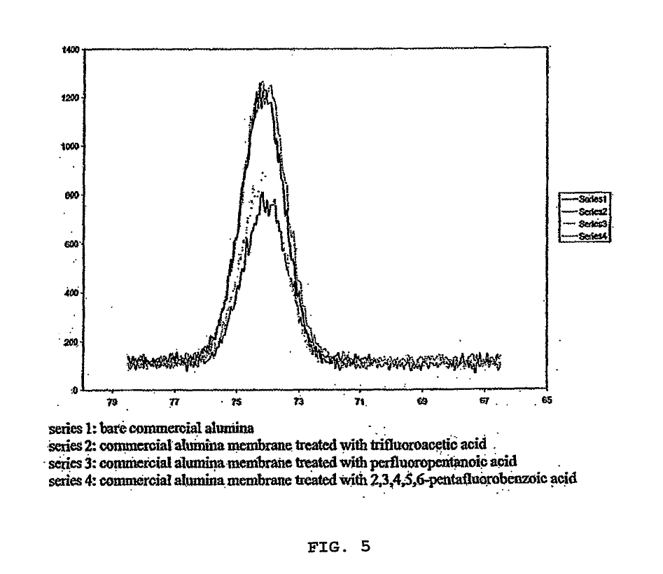

FIG. 5 shows a combination of all of the spectras from FIGS. 1 to 4.

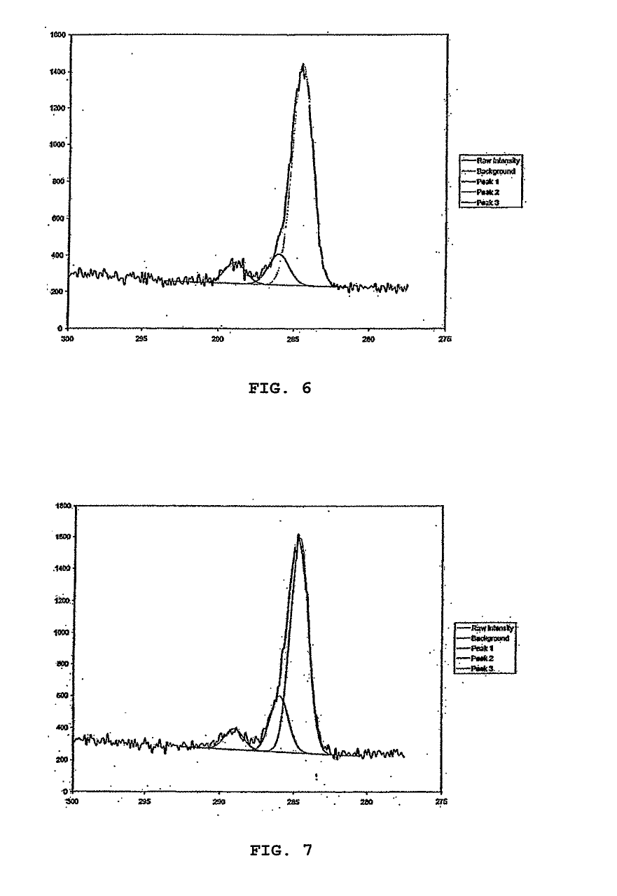

The untreated alumina membrane (Whatman™ Anodisc™ 25), and the treated membranes of Example 1 to 3, were further analysed using the XPS to study the 1s orbital of carbon atoms on the surface of the membranes. XPS, spectras depicting the analysis results are shown in FIGS. 6 to 9 respectively.

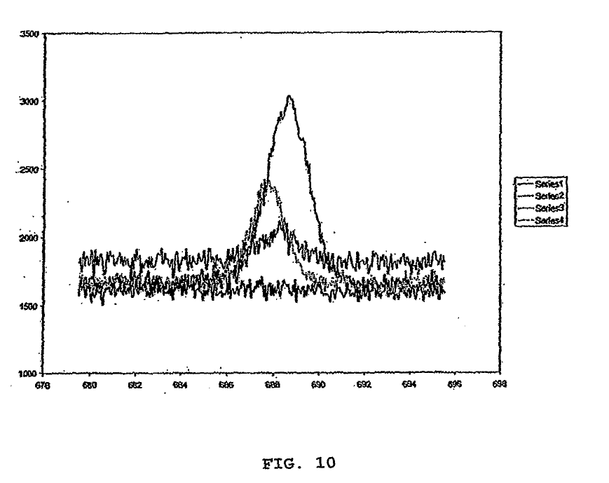

The untreated alumina membrane (Whatman™ Anodisc™ 25), and the treated membranes of Example 1 to 3, were also analysed using the XPS to study the 1s orbital of fluorine atoms on the surface of the membranes. XPS spectras depicting the analysis results of each sample are shown in FIG. 10.

### Examples 4 to 6

The untreated alumina membrane supported on the glass slide was analysed using an X-ray photoelectron spectroscope (XPS) to study the 2p orbital of aluminium atoms on the surface of the untreated alumina membrane.

The treated glass-supported membranes of Examples 4 to 6 were also analysed using the XPS to study the 2p orbital of aluminium atoms on the surface of the treated alumina membranes.

XPS spectras obtained from the analysis of the 2p orbital of aluminium atoms on the surface of the respective membranes are shown in FIG. 11.

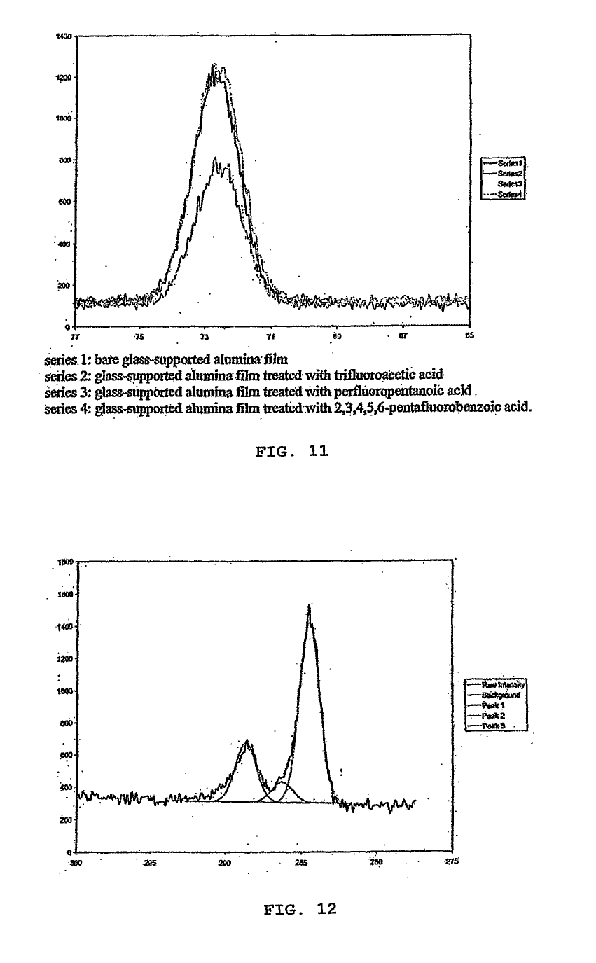

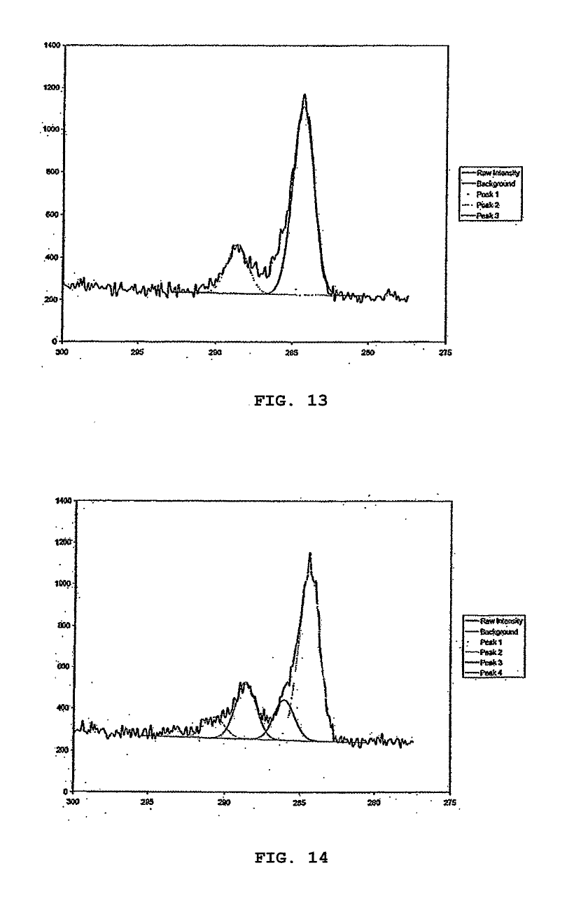

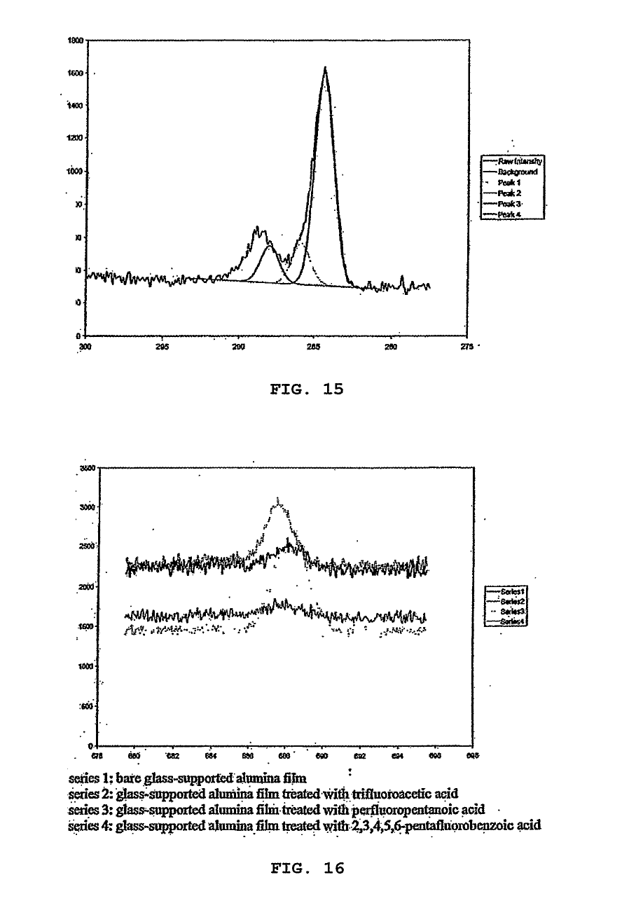

The untreated glass-supported alumina membrane and the treated glass-supported membranes of Examples 4 to 6, were further analysed using the XPS to study the 1s orbital of carbon atoms on the surface of the membranes. XPS spectras depicting the analysis results are shown in FIGS. 12 to 15 respectively.

The untreated glass-supported alumina membrane and the treated glass-supported membranes of Examples 4 to 6, were also analysed using the XPS to study the 1s orbital of fluorine atoms on the surface of the membranes. XPS spectras depicting the analysis results of each sample are shown in FIG. 16.

### Examples 7 to 9

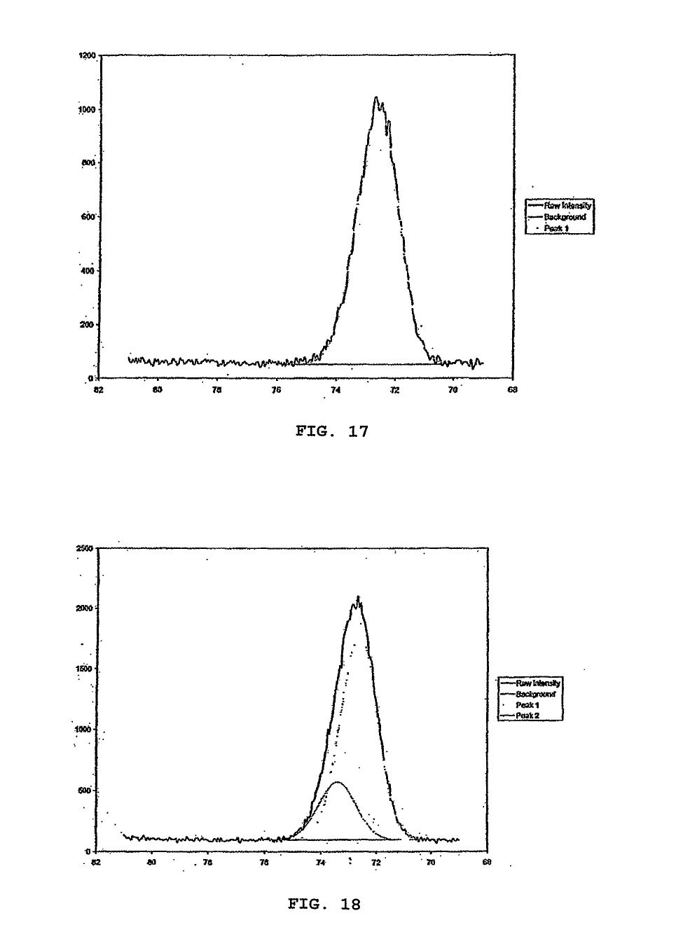

The untreated etched alumina membrane supported on the glass slide was analysed using an X-ray photoelectron spectroscope (XPS) to study the 2p orbital of aluminium atoms on the surface of the untreated alumina membrane. An XPS spectra depicting the analysis result is shown in FIG. 17.

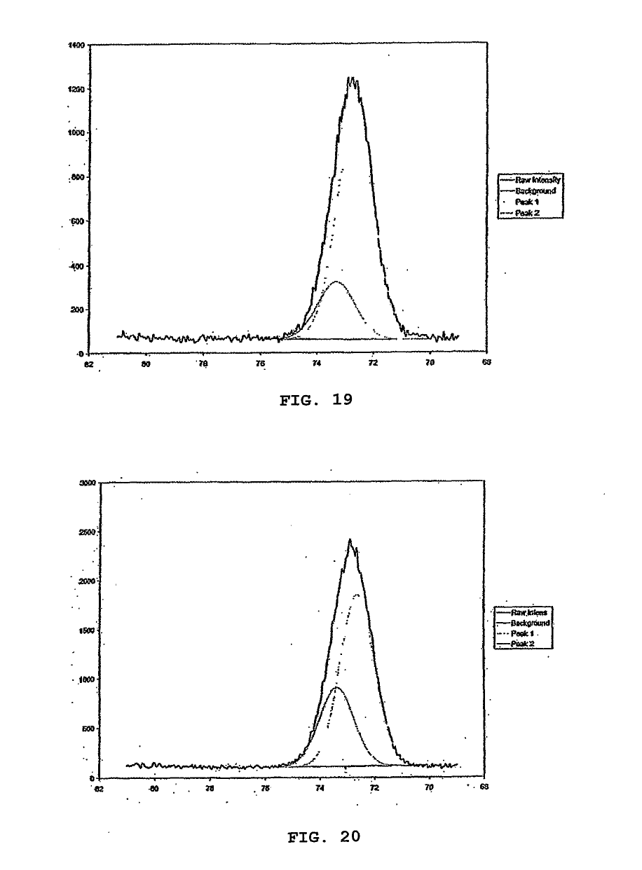

The treated glass-supported membranes of Examples 7 to 9 were also analysed using the XPS to study the 2p orbital of aluminium atoms on the surface of the treated alumina membranes, and XPS spectras depicting the analysis results are shown in FIGS. 18 to 20 respectively.

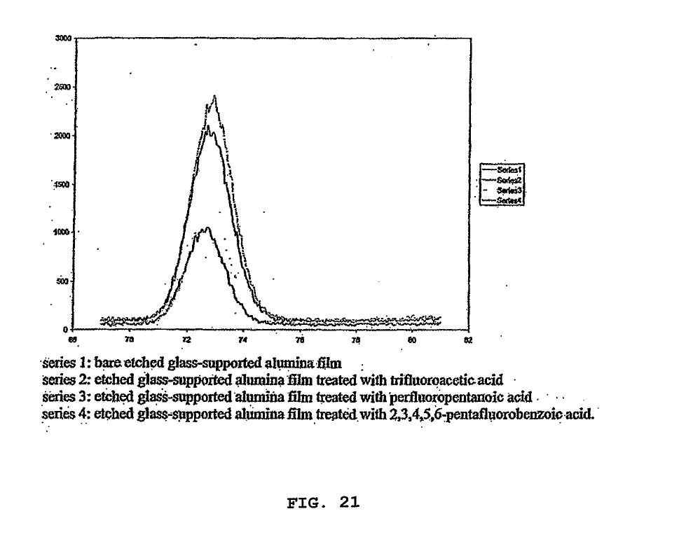

FIG. 21 shows an XPS spectra containing all of the spectras from FIGS. 17 to 20.

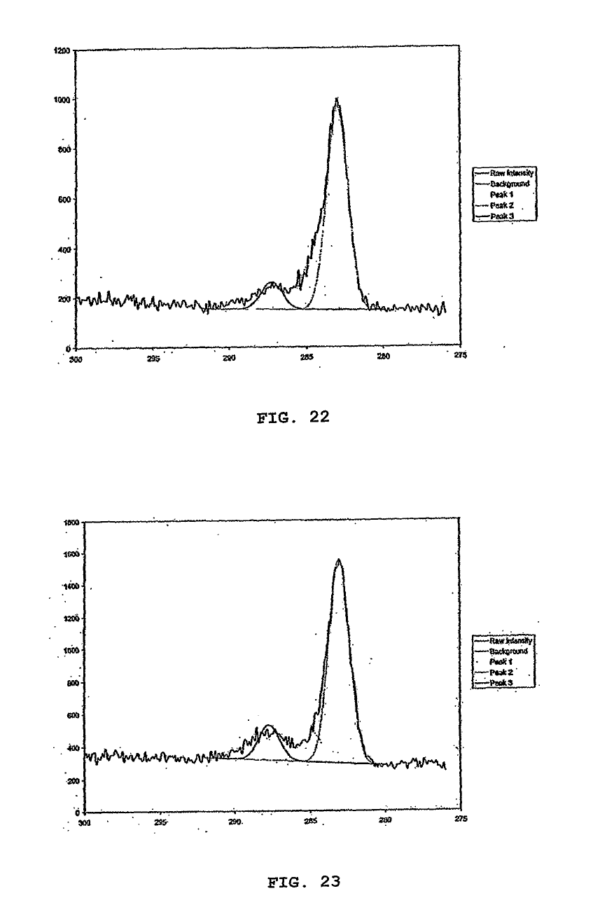

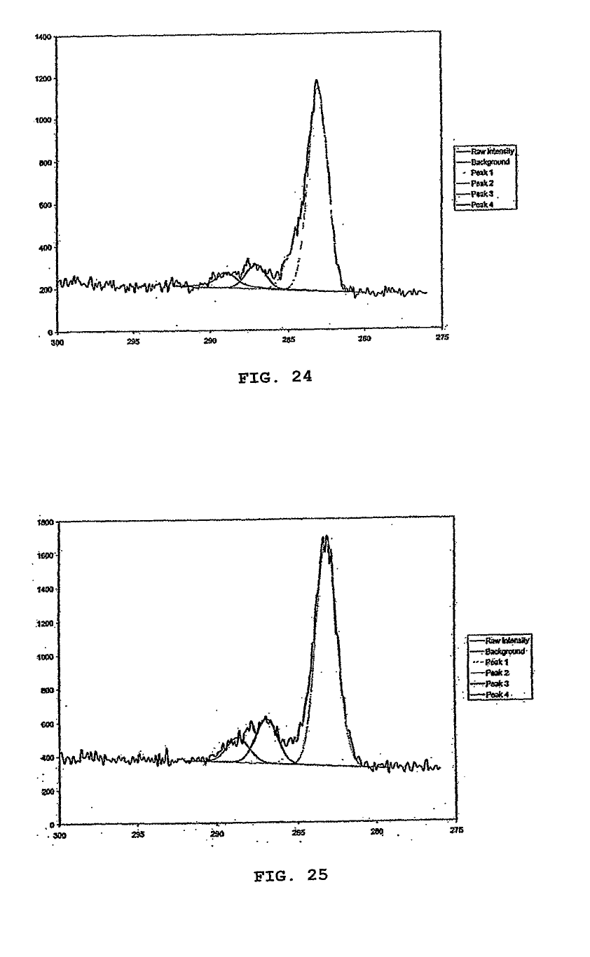

The untreated glass-supported alumina membrane and the treated glass-supported membranes of Examples 7 to 9, were further analysed using the XPS to study the 1s orbital of carbon atoms on the surface of the membranes. XPS spectras depicting the analysis results are shown in FIGS. 22 to 25 respectively.

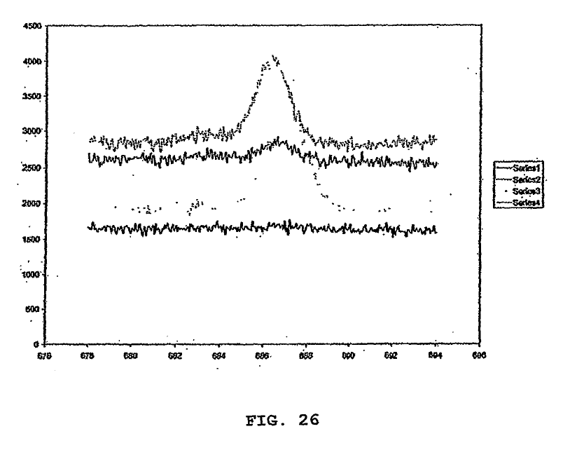

The untreated glass-supported alumina membrane and the treated glass-supported membranes of Examples 4 to 6, were also analysed using the XPS to study the 1s orbital of fluorine atoms on the surface of the membranes. XPS spectras depicting the analysis results of each sample are shown in FIG. 26.

Tabulation of Results from XPS Spectras Obtained From Examples 1 to 9

Table 1 below shows the atomic concentration ratio of fluorine to aluminium on the treated membranes of Examples 1 to 3.

TABLE 1

| | Example 1 | Example 2 | Example 3 |
|---|---|---|---|
| Fluorine (F) atomic concentration (%) | 0.93 | 4.40 | 3.02 |
| Aluminium (Al) atomic concentration | 16.98 | 12.99 | 16.38 |
| (%) | | | |
| F/Al atomic concentration ratio (%) | 0.055 | 0.339 | 0.184 |

Table 2 below shows the atomic concentration ratio of fluorine to aluminium on the treated membranes of Examples 4 to 6.

TABLE 2

| | Example 4 | Example 5 | Example 6 |
|---|---|---|---|
| Fluorine (F) atomic concentration (%) | 0.82 | 4.38 | 1.56 |
| Aluminium (Al) atomic concentration | 19.58 | 19.95 | 21.80 |
| (%) | | | |
| F/Al atomic concentration ratio (%) | 0.042 | 0.220 | 0.072 |

Table 3 below shows the atomic concentration ratio of fluorine to aluminium on the treated membranes of Examples 7 to 9.

TABLE 3

| | Example 7 | Example 8 | Example 9 |
|---|---|---|---|
| Fluorine (F) atomic concentration (%) | 0.65 | 3.83 | 1.85 |
| Aluminium (Al) atomic concentration | 24.83 | 27.73 | 24.70 |
| (%) | | | |
| F/Al atomic concentration ratio (%) | 0.026 | 0.138 | 0.075 |

Table 4 below compares the peaks generated by the 2p orbital of Al atoms on the surfaces of the treated membranes of Examples 1 to 3 and 7 to 9. The values were obtained from the XPS spectras shown in FIGS. 1-5 and 17 to 21.

TABLE 4

| | Ex. 1 | Ex. 2 | Ex. 3 | Ex. 7 | Ex. 8 | Ex. 9 |
|---|---|---|---|---|---|---|
| Original Peak Position (eV) | 72.64 | | | 72.76 | | |
| Al Split Peak (eV) | 73.41 | 73.31 | 73.40 | 73.65 | 73.49 | 73.76 |
| Peak Shift (eV) | 0.77 | 0.69 | 0.76 | 0.89 | 0.73 | 1.0 |

### Example 11

### Results and Discussion of Example 10

### Presence of Halogenated Carboxylic Acid on Surfaces of Treated Membranes of Examples 1 to 9

Referring to FIGS. 10, 16 and 26, the XPS spectras clearly show the presence of fluorine atoms on commercially available alumina membrane of Examples 1 to 3 (see FIG. 10), glass-supported alumina membranes of Examples 4 to 6 (see FIG. 16) and glass-supported alumina membranes of Examples 7 to 9 (see FIG. 26) after chemical treatment with the halogenated carboxylic acid solutions, thereby suggesting the presence of the halogenated carboxylate group of the halogenated carboxylic acid on the surfaces of these treated membranes.

Comparison of Atomic Concentration Ratio of F to Al on the Surfaces of the Treated Membranes of Examples 1 to 9

Referring to Table 1, the atomic concentration ratio of F to Al on the surface of the alumina membrane of Example 2 (i.e., alumina membrane treated with perfluoropentanoic acid CF₃(CF₂)₃COOH) is almost twice that of Example 3 (i.e., alumina membrane treated with 2,3,4,5,6-pentafluorobenzoic acid C₆F₅COOH). This can be due to the presence of a larger number of fluorine atoms in CF₃(CF₂)₃COOH. There are 9 fluorine atoms in CF₃(CF₂)₃COOH as compared to 5 fluorine atoms in C₆F₅COOH.

The atomic concentration ratio of F to Al on the surface of the treated alumina membrane of Example 1 (i.e., alumina membrane treated with trifluoroacetic acid CF₃COOH) is considerably lower than those of the treated membranes of Examples 2 and 3, since the number of fluorine atoms in CF₃COOH is 3, which is lower than those of the acids used in Examples 2 and 3.

The results from Examples 4 to 6 as shown in Table 2 are consistent with those of Table 1. The atomic concentration ratio of F to Al on the surface of the glass-supported alumina membrane treated with CF₃COOH (Example 4) is considerably lower that of the one treated with CF₃(CF₂)₃COOH (Example 5). The atomic concentration ratio of F to Al on the surface of the glass-supported alumina membrane treated with C₆F₅COOH (Example 6) is lower than that of the one treated with CF₃(CF₂)₃COOH (Example 4).

The results from Examples 7 to 9 as shown in Table 3 are also consistent with those of Table 1. The atomic concentration ratio of F to Al on the surface of the glass-supported alumina membrane treated with CF₃COOH (Example 7) is considerably lower that of the one treated with CF₃(CF₂)₃COOH (Example 8). The atomic concentration ratio of F to Al on the surface of the glass-supported alumina membrane treated with C₆F₅COOH (Example 9) is lower than that of the one treated with CF₃(CF₂)₃COOH (Example 8).

The results therefore suggest that a greater surface coverage can be achieved by using halogenated carboxylic acids having a larger number of halogen atoms. This would also suggest that halogenated carboxylic acids having a higher number of halogen (i.e., fluorine) atoms can achieve better adsorption on the surface of the alumina membrane, since the presence of fluorine suggests the presence of the fluorinated carboxylate groups on the surfaces of these treated membranes.

### Covalent Modification of Surface of Treated Alumina Membranes

Referring to FIGS. 1 to 5, a comparison of the XPS graphs of the 2p orbital of Al atoms indicate about 0.6 eV to about 0.7 eV shift in the peaks after treatment of the commercial alumina membranes of Examples 1 to 3 with trifluoroacetic acid, perfluoropentanoic acid and pentafluorobenzoic acid respectively. The shifts of 0.6 eV to 0.7 eV suggest that a covalent modification process is likely to have occurred between the carboxylate groups of the acids and the hydroxyl groups on the surface of the alumina membranes.

Referring to FIG. 11, shifts in the peaks of the XPS graphs are not observed for glass-supported alumina membranes of Examples 4 to 6 after treatment with trifluoroacetic acid, perfluoropentanoic acid and pentafluorobenzoic acid respectively. This can be due to the exposure of the alumina surface to oxalic acid during the anodisation process. Oxalic acid is known to form stable chelating bonds with metal ions and likewise, it is likely that the oxalic acid may have formed a stable surface layer on the alumina surface, thus hindering subsequent surface chemical reactions by the fluorine-substituted carboxylic acids. This is supported by the observation of an unusually high proportion of COOH groups (represented by peak ˜289 eV) present on the chemically untreated glass-supported alumina membrane of Example 4 (see FIG. 12). After etching of the glass-supported alumina membranes using phosphoric acid (Example 7), the proportion of COOH group decreases as can be seen in FIG. 22.

Chemical treatment of glass-supported alumina membranes pre-treated with phosphoric acid in Examples 7 to 9 showed similar peak shifts as those achieved by commercial alumina membranes of Examples 1 to 3. The shifts range between about 0.7 eV and 1.0 eV, thereby indicating that a covalent modification process is likely to have occurred between the carboxylate groups of the acids and the hydroxyl groups on the surface of the alumina membranes.

The results also clearly confirm the assumption that residual oxalic acid left on the alumina films after anodisation in oxalic acid, inhibit the covalent modification process.

### Comparison of XPS Spectra of is Orbital of Carbon Atoms on Surfaces of Treated Membranes of Examples 1 to 9

The XPS spectras of FIGS. 6 to 9 (Examples 1 to 3), FIGS. 12 to 15 (Examples 4 to 6) and FIGS. 22 to 25 (Examples 7 to 9) showed different results for chemically treated alumina surfaces as compared to the untreated surfaces.

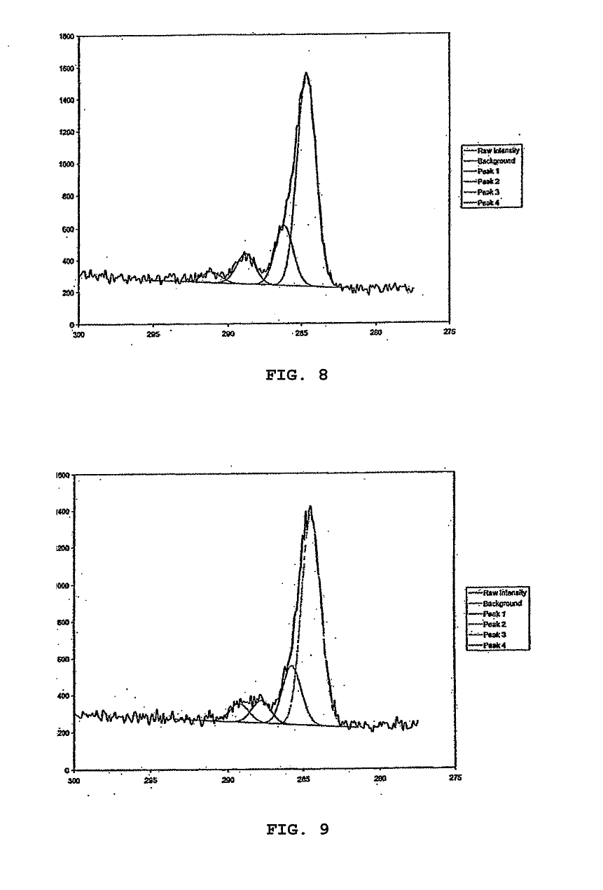

For example, for the alumina membrane of FIG. 8, the peak at 289.61 eV suggests the presence of CF₃ groups. Whereas, on the untreated alumina surface (FIG. 6), this peak corresponding to CF₃ is absent.

Accordingly, the XPS spectras of the 1s orbital of the carbons atoms on the surfaces of the treated membranes further confirm the presence of fluorinated carboxylate groups on the surfaces of the treated membranes.

### Example 12

### Contact Angle Analysis of Treated Alumina Membranes

Glass-supported alumina membranes used in Example 4 were treated in accordance with the methods of Examples 4 to 6, except that the treated membranes were dried in an oven at 120° C. for 24 hours. Contact angle measurements were made on the surfaces of these treated membranes and are shown in Table 5 below.

TABLE 5

| | Contact Angle (°) |
|---|---|
| Glass-supported membrane | 83.1 |
| Treated with CF₃COOH | 105.4 |
| Treated with CF₃(CF₂)₃COOH | 105.0 |
| Treated with C₆H₅COOH | 93.8 |

Glass-supported alumina membranes used in Example 4 were immersed in phosphoric acid (3 vol. %) over a period of 0 minutes, 15 minutes, 30 minutes, 45 minutes and 60 minutes to result in membranes of different pore sizes. The membranes were then treated with the process in accordance with Example 5, except that the treated membranes were dried in an oven at 120° C. for 24 hours. Contact angle measurements were made on the surfaces of these treated membranes and are shown in Table 6 below.

TABLE 6

| | Etched Glass-supported | Alumina treated with |
|---|---|---|
| Etching time (minutes) | alumina | CF3(CF2)3COOH |
| 0 | 83.1 | 105.0 |
| 15 | 96.3 | 103.5 |
| 30 | 98.1 | 98.6 |
| 45 | 111.1 | 111.7 |
| 50 | 111.4 | 104.2 |

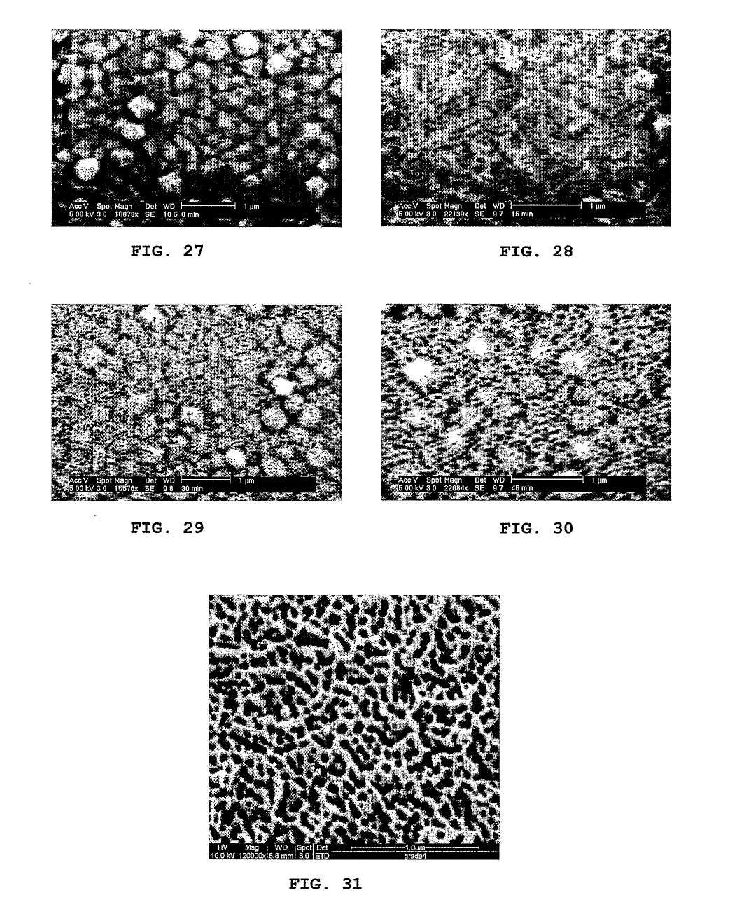

Scanning Electron Microscope (SEM) micrographs of the glass-supported alumina membranes exposed to the phosphoric acid for the various periods of time are shown in FIGS. 27 to 31 respectively.

The range of pore sizes achieved for the glass-supported alumina membranes exposed to phosphoric acid for 0 minutes, 15 minutes, 30 minutes and 45 minutes, are 35nm-45nm, 40 nm-50 nm, 50 nm-70 nm and 80 nm-90 nm respectively.

The glass-supported alumina membrane that was exposed to phosphoric acid for 60 minutes was damaged.

Glass-supported alumina film membranes, prior to drying in the oven, were observed to be hydrophilic with measured contact angles at room temperature of about 24°. When these membranes were dried in the oven at 120° C. for 24 hours, the measured contact angles increased to 83.1°±2.5°. Re-hydration by immersing the membranes in de-ionised water resulted in a contact angle values of 48.3°±3.2°. Similar trends were observed for the glass-supported alumina film membranes with different pore sizes. The differences in contact angle values before and after drying in the oven can be due to the amount of residual water trapped within the pores of the undried membranes. Therefore, for contact angle measurements, all alumina membranes were dried thoroughly in the oven at 120° C. before carrying out the measurements.

Results of Table 5 show an increase in contact angle of the alumina surface after chemical treatment, suggesting that more hydrophobic surfaces were formed after chemical modification.

Referring to Table 6, it can be seen that the contact angle results for untreated glass-supported alumina membranes with different pore sizes, indicate an increase in the contact angle as the pore size increases, thereby suggesting an increase in hydrophobicity of the surface. However, the same trend is not observed for the chemically treated glass-supported alumina membranes of different pore sizes, and the contact angle values remain relatively constant regardless of the pore size.

The effects of increasing hydrophobicity by changing pore sizes and by chemical modification are clearly not additive. This is not surprising since larger pore sizes means more contact with air pockets within the pore channels. The air pockets in the pores of the membranes exert little attractive forces on water droplets and hence, an alumina sample with large pore sizes are similar to ones in which the pore channels are filled with hydrophobic materials. Increasing pore sizes for the chemically treated alumina membranes would have little effect on hydrophobicity as both the surface and the air pockets have similar low attractive forces for water.

It should be noted that at the short etching time of 10 minutes, chemical treatment with perfiuropentanoic acid does not yield the same surface hydrophobicity at all parts of the alumina sample. This is likely due to incomplete removal of surface oxalic acids which hinder surface chemical reactions by fluorine-substituted carboxylic acids as observed above. Hence, contact angle measurements were carried out on glass-supported alumina samples etched for times longer than 10 minutes.

The contact angle results indicate that chemical modification of alumina membranes changes the surface hydrophobic property of alumina, whilst at the same time, showed little variation despite changes in the pore sizes. Accordingly, the treated membranes can be employed in applications requiring consistent surface hydrophobicity or in applications in which this property is critical to the application performance.

### Applications

It will be appreciated that the method of treating an alumina film can modify the surface properties of alumina film, to thereby extend its use to applications that require a less hydrophilic or more hydrophobic surface. Such applications include providing hydrophobic surfaces in micro-systems and in the separation and purification of protein molecules.

It will be appreciated that the method is simple and inexpensive to carry out as compared to existing methods which require high pressure vials as outlined in the Background section of the specification.

It will be apparent that various other modifications and adaptations of the invention will be apparent to the person skilled in the art after reading the foregoing disclosure without departing from the spirit and scope of the invention and it is intended that all such modifications and adaptations come within the scope of the appended claims.

In the claims:

1. A method of treating an alumina film comprising the step of:
(a) exposing an alumina film to a carboxylic acid in solution under conditions to reduce hydrophilic properties of the surface of said alumina film.

2. The method as claimed in claim 1, wherein said carboxylic acid has the formula R(COOH)ₙ, wherein R is an aliphatic hydrocarbon group or an aromatic hydrocarbon group; and n is 1 or 2.

3. The method as claimed in claim 2, wherein R is an optionally halogen-substituted aliphatic hydrocarbon comprising one or more straight chain or branched chain alkyls, alkenyls, alkynyls and combinations thereof.

4. The method as claimed in claim 3, wherein said alkyl has 1 to 6 carbon atoms and said alkenyls and alkynyls have 2 to 6 carbon atoms.

5. The method as claimed in claim 1, wherein said carboxylic acid is a halogen-substituted carboxylic acid.

6. The method as claimed in claim 5, wherein the number of halogen atoms of said halogen-substituted carboxylic acid is in the range of 1 to 10.

7. The method as claimed in claim 5, wherein said halogen is fluorine.

8. The method as claimed in claim 7, wherein the fluorine-substituted carboxylic acid comprises one or more of fluorine-substituted acetic acid, fluorine-substituted propanoic acid, fluorine-substituted butanoic acid, fluorine-substituted pentanoic acid, fluorine-substituted hexanoic acid and combinations thereof.

9. The method as claimed in claim 2, wherein R is an optionally halogen-substituted aromatic hydrocarbon group comprising one or more of benzyl, toluyl, xylyl, naphthyl and combinations thereof.

10. The method as claimed in claim 7, wherein said halogen-substituted carboxylic acid is a fluorine-substituted carboxylic acid comprising one or more of fluorine-substituted benzoic acid, fluorine-substituted toluic acid, fluorine-substituted naphthalic acid and combinations thereof.

11. The method as claimed in claim 1, wherein said carboxylic acid solution comprises a carboxylic acid dissolved in an organic solvent.

12. The method as claimed in claim 11, wherein said organic solvent is a non-polar solvent.

13. The method as claimed in claim 12, wherein said non-polar solvent is an optionally halogen-substituted aliphatic hydrocarbon group comprising one or more of straight or branched chain alkanes, ketones, ethers and mixtures thereof.

14. The method as claimed in claim 12 wherein said alkane has 1 to 6 carbon atoms, said ketone has 2 to 6 atoms and said ether has 2 to 6 atoms.

15. The method as claimed in claim 11, wherein said organic solvent is a halogen-substituted organic solvent.

16. The method as claimed in claim 15, wherein the number of halogen atoms of said halogen-substituted organic solvent is in the range of 1 to 6.

17. The method as claimed in claim 15, wherein said halogen is chlorine.

18. The method as claimed in claim 17, wherein the chlorine-substituted organic solvent comprises at least one of chloroethane, chloropropane, chlorobutane, chloropentane, chlorohexane and combinations thereof.

19. The method as claimed in claim 1, wherein said carboxylic acid solution has a concentration from about 0.01M to about 0.1M.

20. The method as claimed in claim 1, wherein the conditions of said exposing step (a) comprise the step of:
(b) refluxing said alumina film in said carboxylic acid solution at a temperature, pressure and time effective to react said carboxylic acid with a hydroxide of said alumina film.

21. The method as claimed in claim 20, wherein said carboxylic acid solution comprises a carboxylic acid in an organic solvent and wherein said refluxing step (b) comprises the step of:
(b1) maintaining said temperature at or above the boiling point of the organic solvent.

22. The method as claimed in claim 21, wherein said temperature in said maintaining step (b1) is from about 60° C. to about 100° C.

23. The method as claimed in claim 20, wherein said refluxing step (b) comprises the step of:
(b2) refluxing said alumina film in said carboxylic acid solution for a time of from about 2 hours to about 5 hours.

24. The method as claimed in claim 20, wherein said refluxing step (b) is undertaken in a vacuum.

25. The method as claimed in claim 24, wherein said refluxing step (b) comprises the step of: (b3) maintaining the gauge pressure at 20 kPa to about 160 kPa.

26. The method as claimed in claim 20, comprising, after step (b), the step of: (c) removing the resulting treated alumina film from said carboxylic acid solution.

27. The method as claimed in claim 15, comprising, after step (c), the step of: (d) washing the resulting treated alumina film with an inert solvent.

28. The method as claimed in claim 16, comprising, after step (d), the step of: (e) drying the resulting treated alumina.

29. The method as claimed in claim 1, comprising, before step (a), the step of: (f) forming an aluminum film on a substrate by magnetron sputtering of an aluminum target; and (g) anodizing the formed aluminum film to form said alumina film.

30. The method as claimed in claim 29, comprising, after step (g) but before step (a), the step of:
(i) immersing said alumina film into an acid.

31. The method as claimed in claim 1, wherein said
alumina film is a membrane.

32. The method as claimed in claim 1, wherein said exposing causes said alumina film to become generally hydrophobic.

33. A method of treating an alumina film comprising the step of:
(a) providing an alumina film comprising a hydroxide;
(b) providing an optionally halogen-substituted carboxylic acid in solution;
(c) exposing said alumina film to said solution under conditions to react said hydroxide with said optionally halogen-substituted carboxylic acid to reduce hydrophilic properties of a surface of said film.

34. The treated alumina film made by the method of claim 1.

35. (canceled)

36. (canceled)

37. An alumina film having carboxylate groups bonded to the surface of said alumina film.

38. The alumina film as claimed in claim 37, wherein said carboxylate groups are substituted with halogen atoms.

39. The alumina film as claimed in claim 38, wherein said halogen is fluorine.

40. The alumina film as claimed in claim 37, wherein the amount of said carboxylate groups bonded to the surface of said alumina film render said surface generally hydrophobic.
